(19) United States
(12) Patent Application Publication
(10) Pub. No.: US 2007/0216436 A1
(43) Pub. Date: Sep. 20, 2007

(54) Structure and fabricating method of conductive trace

(76) Inventor: Chien-Han Ho, Somerset, NJ (US)

Correspondence Address: BIRCH STEWART KOLASCH & BIRCH, PO BOX 747, FALLS CHURCH, VA, 22040-0747, US

(21) Appl. No.: 11/374,026

(22) Filed: Mar. 14, 2006

(51) Int. Cl. G01R 31/26

(52) U.S. Cl. 324/765

(57) ABSTRACT

The present invention provides a structure and fabricating method of forming conductive traces on a printed circuit board. The method comprises the steps of (a) providing an insulating substrate; (b) forming grooves on the insulating substrate; and (c) filling a first colloid which has a bridging effect with the insulating substrate into the grooves; and (d) filling a second colloid which reacts with the first colloid into the conductive traces.

### BACKGROUND OF THE INVENTION

1. Field of the Invention

The present invention generally relates to printed circuit boards, and more particularly relates to a structure and method of fabricating conductive traces on a printed circuit board.

2. The Prior Arts

A printed circuit board (PCB) contains electrical wiring formed by appropriate methods on an insulating material to interconnect electronic components to be mounted on the printed circuit board.

Conventionally, the electrical wiring or conductive traces of a PCB is formed by gluing a copper foil to an insulating substrate, and then removing the unwanted portion of the copper foil by drilling, etching, or appropriate methods.

However, with these conventional methods, satisfactory insulation among the conductive traces is difficult to achieve. Therefore, to avoid interference, spacing among the conductive traces are usually enlarged. As a result, the circuit layout density and the form factor of the PCB cannot be reduced. Moreover, copper conductive traces are glued to the substrate and frequently fall off after a period of usage, causing open circuit to the traces. Besides, solution used in the etching process is hazardous to the environment.

### SUMMARY OF THE INVENTION

Accordingly, a primary objective of the present invention is to provide a structure and fabricating method of conductive traces by filling conductive colloid into grooves formed on the PCB substrate so as to achieve superior insulation therebetween.

Another objective of the present invention is to provide a structure and fabricating method of conductive traces to increase circuit layout density.

Yet another objective of the present invention is to provide a structure and fabricating method of conductive traces to prevent open circuit along the conductive traces caused by copper foil falling off.

Still another objective of the present invention is to provide a structure and fabricating method of conductive traces to prevent environmental hazards by avoiding the use of solution in etching process.

One further objective of the present invention is to provide a structure and fabricating method of conductive traces to simplify the fabricating process and to reduce the production cost.

In order to accomplish the above objectives, the present invention provides a structure and fabricating method of conductive traces comprising (a) providing an insulating substrate; (b) forming groove on the insulating substrate; (c) filling a first colloid which has bridging effect on the insulating substrate into the grooves; and (d) filling a second colloid which is chemically reactive to the first colloid into the groove so that the two colloids react to form the conductive traces

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1A˜1C are schematic views showing the various steps of forming conductive traces according to the fabricating method of the present invention.

### DETAILED DESCRIPTION OF THE PREFERRED EMBODIMENT

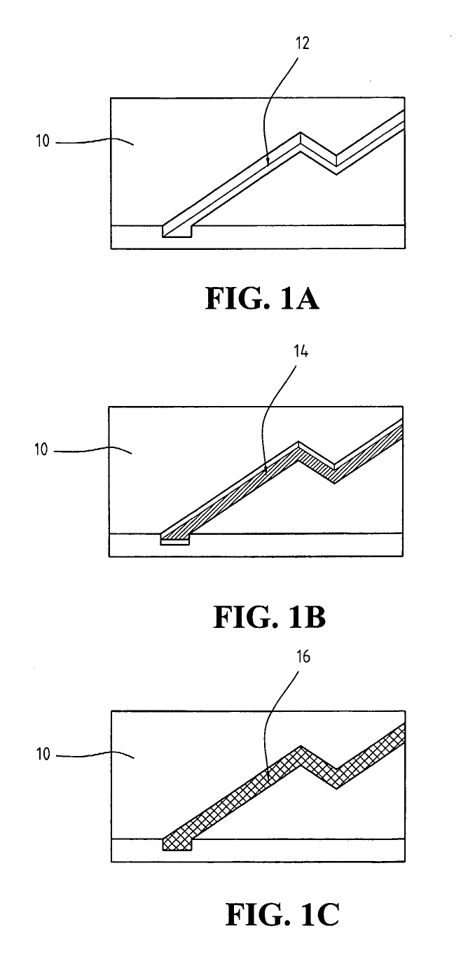

FIG. 1A˜1C are schematic views showing the various steps of forming conductive traces according the fabricating method of the present invention. As shown, fabricating the conductive traces comprises 3 steps: (a) forming grooves 12 on the surface of an insulating substrate according to the required circuit layout as shown in FIG. 1A; (b) filling a first colloid 14 into the grooves 12 as shown in FIG. 1B; and (c) forming the conductive traces 16 along the grooves 12 as shown in FIG. 1C.

The conductive traces 16 are obtained by filling a second colloid (not shown) into the grooves 12. The second colloid reacts with the first colloid 14 and the two jointly turn into the solid conductive traces 16. The first colloid 14 and the second colloid can be the Electrically Conductive Epoxies provided by the Cotronics™ corporation. Cotronics provides the colloids separately, and the users can mix the colloids by themselves. Please note that the first colloid 14 and the second colloid used in the present invention are not limited to be those provided by Cotronics, and those colloids meeting the criteria (two colloids are non-solid before being mixed together and become conductive after being mixed together) are suitable for the present invention.

As shown in FIG. 1A, the grooves 12 are formed on an insulating substrate 10 of a PCB by laser or machinery process in accordance with a desired circuit layout.

As shown in FIG. 1B, the first colloid 14 is filled into the grooves 12 by precision coating techniques such as inkjet printing or screen printing. Please note that after the first colloid 14 is filled, a thorough inspection for any discontinuity of the first colloid 14 along the grooves 12 is necessary, and any residual of the first colloid 14 outside the grooves 12 has to be removed as well. The first colloid 14 should be able to produce a bridging effect with the insulating substrate 10 so that the subsequently formed conductive traces 16 cling to the insulating substrate 10 tightly, therefore avoiding the falling off and open circuit problems of the prior arts.

As shown in FIG. 1C, the second colloid is filled in the grooves and reacts with the first colloid 14 to produce the conductive traces 16. Similarly, any residual of the second colloid outside the grooves 12 has to be removed.

Up to this point, the formation of the conductive traces 16 is completed. The conduct traces 16 thus formed, as they are embedded into the substrate 10, enjoy superior insulation among each other provided by the side walls of the grooves 12. As such, the circuit layout density could be increased. Besides, the fabricating method according to the present invention does not use any etching solution and is therefore more environmental friendly. Moreover, the present invention omits the etching processes used in the prior art and thereby reduces the cost of production.

Additionally, to further enhance the conduction property of the conductive traces 16, an appropriate conductive material could be coated on the conductive traces 16 by spraying, electroplating, or evaporating.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A method of fabricating a plurality of conductive traces on a printed circuit board in accordance with a circuit layout, comprising the steps of:
(1) providing an insulating substrate for said printed circuit board;
(2) forming a plurality of grooves on a surface of said insulating substrate in accordance with said circuit layout;
(3) filling a first colloid which produces a bridging effect with said insulating substrate into said grooves; and
(4) filling a second colloid which is reactive to said first colloid to form said conductive traces.

2. The method as claimed in claim 1, wherein said step (4) further comprises: coating an appropriate conductive material on said conductive traces.

3. The method as claimed in claim 1, wherein said step (3) further comprises:
removing residuals of said first colloid outside of said grooves.

4. The method as claimed in claim 1, wherein said step (4) further comprises:
removing residuals of said second colloid outside of said grooves.

5. The method of fabricating a conductive trace as claimed in claim 1, wherein said conductive traces are solid conductors formed by the reaction of said first colloid and said second colloid.

6. A structure of conductive traces on an insulating substrate of a printed circuit board, wherein
said conductive traces are embedded inside a plurality of grooves on the surface of said insulating substrate,
said conductive traces are formed by the reaction of a first colloid and a second colloid; and
said first colloid has a bridging effect with said insulating substrate.

7. The structure as claimed in claim 6, wherein said conductive traces are solid conductors formed by the reaction of said first colloid and said second colloid.

8. The structure as claimed in claim 6, wherein an appropriate conductive material is coated on said conductive traces.
